(19) United States
(12) Patent Application Publication
(10) Pub. No.: US 2026/0219702 A1
(43) Pub. Date: Jul. 30, 2026

(54) BUILT-IN SYNCHRONIZER CLOCK GATING FOR LOW POWER CONSUMPTION

(71) Applicant: Morse Micro Pty. Ltd., Surry Hills NSW (AU)

(72) Inventor: Tomas Kubec, Surry Hills NSW (AU)

(21) Appl. No.: 19/300,266

(22) Filed: Aug. 14, 2025

(30) Foreign Application Priority Data
Jan. 28, 2025 (AU) 2025900213

(51) Int. Cl. G06F 1/08; H03K 19/21

(52) U.S. Cl. CPC G06F 1/08; H03K 19/21

(57) ABSTRACT

A digital circuit includes a first digital system operating in a first domain, a second digital system operating in a second domain, and a synchronizer for synchronizing data transfer operations across a domain boundary between the first and second domains. The synchronizer generates a synchronous output signal for the second digital system from an asynchronous input signal. The synchronizer includes a clock gating logic and a synchronizer flop bank comprising multiple synchronization flip flops. The clock gating logic receives the asynchronous input signal, the synchronous output signal, and a clock signal, and adaptively gates the clock signal according to the synchronous input signal and the synchronous output signal. The synchronizer flop bank receives the asynchronous input signal and the clock signal to generate the synchronous output signal, where the clock signal is adaptively gated by the clock gating logic.

### CROSS REFERENCE TO RELATED APPLICATION

The present application claims priority from Australian provisional patent application number 2025900213 filed on 28 Jan. 2025, the contents of which are incorporated herein by cross-reference.

### FIELD OF THE INVENTION

The present disclosure generally relates to digital circuit design. Specifically, aspects of the present disclosure are related to synchronizer clock gating in digital circuits.

### BACKGROUND

A modern System on Chip (SoC) integrates multiple modules or systems, each module or system may be operated in different clock domains. These asynchronous systems in different clock domains are operating at different clock frequencies. That is, each system may operate on a distinct clock signal to trigger its internal operations for improved performance. Fully synchronizing all clock domains and reset domains can be impractical due to the associated engineering complexity, increased power consumption, and elevated design risk. A reset domain refers to a grouping of logic components that are controlled by the same reset signal. The reset signal initiates the states of flip flops, register, and sequential elements to a known condition, ensuring the module begins operation in a defined state. To enable reliable data transfer between systems operating in different clock or reset domains, an interface is often required to synchronize the input and output signals. Such a synchronization interface helps prevent signal metastability and glitches. Metastability occurs when a signal exists in an indeterminate state between 0 and 1. Generally, glitches arise from input timing mismatches, either due to delays in signal arrival, delays within the module or system when updating its output in response to input changes, or a combination of both. Even if two modules or systems operate at the same frequency, an arbitrary phase difference can also lead to metastability issues. The interface, or so called a synchronizer, is used to synchronize data transfer operations across a clock domain boundary to avoid timing-related data errors. Clock Domain Crossing (CDC) or Reset Domain Crossing (RDC) library constrains all the basic components used for synchronization across high abstraction systems. These basic components in CDC or RDC library allow safely cross different clock domains or reset domains within the SoC.

### SUMMARY

The following summary presents technical features relating to one or more aspects of disclosed herein and should not be considered as an extensive overview relating to all contemplated aspects. Accordingly, the following summary has the sole purpose of presenting certain concepts relating to one or more embodiments relating to a clock generator disclosed herein in a simplified form to precede the detailed description presented below.

Embodiments of a digital circuit having multiple digital systems comprise a first digital system, a second digital system, and a synchronizer coupled to the first and second digital systems for synchronizing data transfer operations across a domain boundary. The first digital system operates in a first domain while the second digital system operates in a second domain. The synchronizer generates a synchronous output signal suitable for the second digital system from an asynchronous input signal receiving from the first digital system. Embodiments of the synchronizer comprise a clock gating logic and a synchronizer flop bank. The clock gating logic receives the asynchronous input signal and synchronous output signal, and a clock signal, and adaptively gates the clock signal according to the asynchronous input signal and the synchronous output signal. The synchronizer flop bank comprises a number of synchronization flip flops for receiving the asynchronous input signal and the clock signal to generate the synchronous output signal, where the clock signal could be adaptively gated by the clock gating logic. In some embodiments, the first and second domains are different clock domains capable of operating at different clock frequencies. In some embodiments, the first and second domains are different reset domains, that are resetting by different reset signals.

The clock gating logic propagates the clock signal upon detecting there is a level difference between the asynchronous input signal and the synchronous output signal and gates the clock signal upon detecting no level difference exists according to some embodiments of the present invention. In some embodiments, the clock gating logic transitions from gating the clock signal to propagate the clock signal after detecting a level difference between the asynchronous input signal and synchronous output signal last for at least a predetermined number of clock cycles. For example, the predetermined number of clock cycles corresponds to the number of synchronization flip flops in the synchronizer flop bank.

In one embodiment, the clock gating logic includes an XOR gate and a clock gate latch, where inputs to the XOR gate are the asynchronous input signal and the synchronous output signal, and an output of the XOR gate is coupled to an enable pin of the clock gate latch, and the clock signal is coupled to a clock pin of the clock gate latch. The clock gating logic gates the clock signal for the synchronizer flop bank when there is no level difference between the synchronous input signal and the synchronous output signal.

The synchronizer receives an asynchronous reset signal according to some embodiments, the clock gating logic only propagates the clock signal upon detecting a level difference between the asynchronous input signal and synchronous output signal and when the asynchronous reset signal is inactive. In one embodiment, the clock gating logic includes an XOR gate, an AND gate, and a clock gate latch. Inputs to the XOR gate are the asynchronous input signal and the synchronous output signal, whereas inputs to the AND gate are the synchronous reset signal and an output of the XOR gate. An output of the AND gate is coupled to an enable pin of the clock gate latch and the clock signal is coupled to a clock pin of the clock gate latch, and the clock gate latch adaptively gates the clock signal for the synchronizer flop bank according to the output of the AND gate.

In some other embodiments, the synchronizer receives a synchronous reset signal, and the clock gating logic only propagates the clock signal upon detecting a level difference between the asynchronous input signal and the synchronous output signal or the synchronous reset signal is active. For example, the clock gating logic includes an XOR gate, an OR gate, and a clock gate latch. Inputs to the XOR gate are the asynchronous input signal and the synchronous output signal, inputs to the OR gate are the synchronous reset signal and an output of the XOR gate, and an output of the OR gate is coupled to an enable pin of the clock gate latch and the clock signal is coupled to a clock pin of the clock gate latch. The clock gate latch adaptively gates the clock signal for the synchronizer flop bank according to the output of the OR gate.

Some examples of the synchronizer include a reset synchronizer used for synchronizing logic high or logic low asynchronous resets, a level synchronizer for level-based data or control signal synchronization, and a pulse synchronizer for pulse-based data or control signal synchronization. The level synchronizer may receive a synchronous reset input or an asynchronous reset input.

An aspect of the present invention introduces a synchronizing method for synchronizing data transfer across a domain boundary between a first digital system and a second digital system. The method includes receiving an asynchronous input signal from the first digital system, receiving a clock signal for synchronizing the asynchronous input signal, generating a synchronous output signal by a synchronizer flop bank from the asynchronous input signal, detecting if there is a level difference between the asynchronous input signal and synchronous input signal output signal, and controlling a delivery of the clock signal to the synchronizer flop bank through a clock gating logic based on the detecting result. The clock signal is gated by the clock gating logic upon detecting there is no level difference between the asynchronous input signal and synchronous output signal for minimizing power consumption. In some embodiments, the synchronizing method further includes receiving an asynchronous reset signal. The clock gating logic propagates the clock signal when a level difference is detected between the asynchronous input signal and the synchronous output signal and when the asynchronous reset signal is inactive, otherwise the clock gating logic gates the clock signal. In some other embodiments, the synchronizing method further includes receiving a synchronous reset signal. The clock gating logic propagates the clock signal when a level difference is detected between the asynchronous input signal and the synchronous output signal or when the synchronous reset signal is active, otherwise the clock gating logic gates the clock signal. An embodiment of the clock gating logic transitions from gating the clock signal to propagate the clock signal after detecting a level difference between the synchronous input signal and synchronous output signal last for at least a predetermined number of clock cycles.

Other objects and advantages associated with the aspects disclosed herein will be apparent to those skilled in art based on the accompanying drawings and detailed description.

### BRIEF DESCRIPTION OF THE DRAWINGS

Illustrative aspects of the present application are described in detail below with reference to the following drawing figures:

FIG. 1 illustrates a block diagram of a synchronizer having a clock gating logic used for level-based data or control signal according to an embodiment of the present invention.

FIG. 2 illustrates a block diagram of a reset synchronizer having a clock gating logic used for synchronizing active high asynchronous resets according to an embodiment of the present invention.

FIG. 3 illustrates a block diagram of another reset synchronizer having a clock gating logic used for synchronizing active low asynchronous resets according to an embodiment of the present invention.

FIG. 4 illustrates a block diagram of a synchronizer having a clock gating logic without a reset input signal according to an embodiment of the present invention.

FIG. 5 illustrates a block diagram of a synchronizer having a clock gating logic with a synchronous reset input according to an embodiment of the present invention.

FIG. 6 is a flowchart illustrating an embodiment of a synchronizing method for synchronizing data transfer across a domain boundary between two digital systems.

### DETAILED DESCRIPTION

Certain aspects and embodiments of this disclosure are provided below. Some of these embodiments may be applied independently and some of them may be applied in conjunction as would be apparent to those of skill in the art. In the following description, for the purposes of explanation, specific details are set forth to provide a thorough understanding of aspects of the application. However, it will be apparent that various embodiments may be practiced without these specific details. The following description of the embodiments will provide those skilled in the art with an enabling description for implementing an example aspect. Changes may be made in the function and arrangement of elements without departing from the spirit and scope of the application as set forth in the claims.

The general issue with synchronizer for synchronizing data transfer across systems when it comes to power consumption is that synthesis has no ability to gate the clock fed to these synchronizers. That is because the digital logic around flops in the synchronizer is asynchronous, making it impossible to automatically implement safe clock gating logic by the existing synthesis tool. There are no clock gating of these synchronization flip flops, causing increased but unnecessary power consumption all the time. It is desired to only provide the clock signal to the synchronization flip flops when these synchronization flip flops are actively propagating a change from one digital domain to the other digital domain.

Embodiments of the present invention insert a clock gating logic enabling propagation of the clock signal to the synchronization flip flops only when a signal change is happening between two clock or reset domains, otherwise the clock gating logic keeps the clock gated to save power. Various embodiments of encapsulated reset or data synchronizers are specifically designed to unify the CDC or RDC structure, simplify the CDC or RDC analysis, and make it possible to apply the constraints automatically. Some embodiments of the dedicated synchronizers include a reset synchronizer rst_sync used for synchronizing asynchronous resets active high, a reset synchronizer rstn_sync used for synchronizing asynchronous resets active low, a level synchronizer level_sync used for level-based data or control signal synchronization, and a pulse synchronizer for pulse-based data or control signal synchronization. In some other embodiments, a level synchronizer level_sync_noreset used for level-based data or control signal synchronization except it has no reset, and a level synchronizer level_sync_syncreset used for level-based data or control signal synchronization except it has synchronous reset input. Various designs of the reset synchronizer can be used for synchronizing logic high or logic low asynchronous resets.

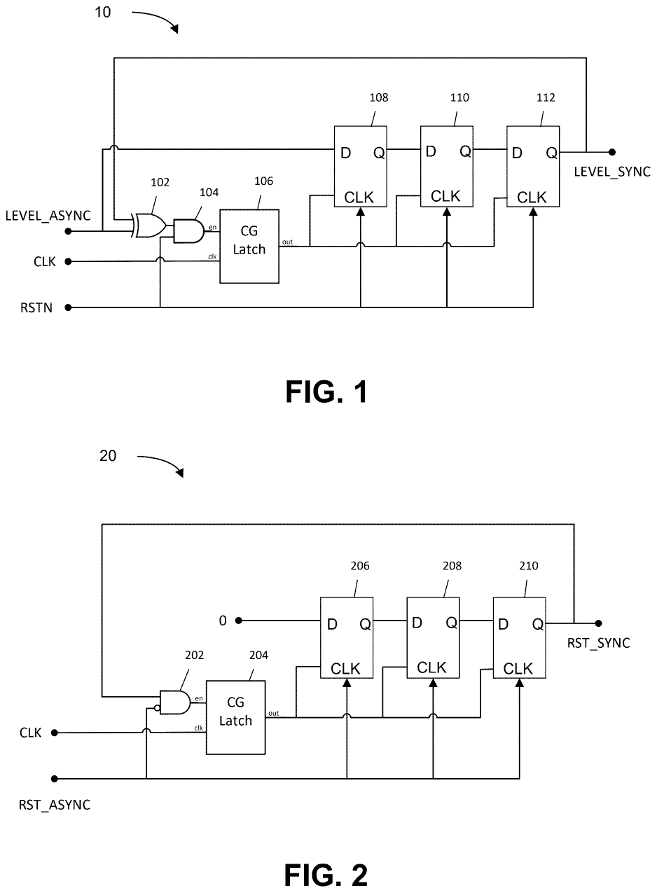

FIG. 1 illustrates an embodiment of a 3-stage level synchronizer 10 with a clock gating logic composing of an XOR gate 102, an AND gate 104, and a clock gate latch (CG Latch) 106. Inputs of this level synchronizer 10 include an asynchronous input signal (LEVEL_ASYNC), a clock signal (CLK), and a reset signal (RSTN). The output of the level synchronizer 10 is a synchronous output signal (LEVEL_SYNC). The asynchronous input signal (LEVEL_ASYNC) and the synchronous output signal (LEVEL_SYNC) are fed to the XOR gate 102, and output of this XOR gate 102 together with the reset signal (RSTN) are provided to the AND gate 104. The output of the AND gate 104 goes to an enable pin of the clock gate latch 106. A clock pin of the clock gate latch 106 receives the input clock signal (CLK), where the clock gate latch 106 only propagates the clock signal (CLK) to the synchronizer flop bank 108, 110, and 112 when there is a level difference detected by the XOR gate 102 and the reset signal indicates reset is not required. In this embodiment, the reset signal is logic low (logic 0) for resetting whereas the reset signal is logic high (logic 1) for not resetting. The CG latch 106 gates the clock signal (CLK) when either the reset signal indicates reset is required or when the output of the XOR gate 102 is logic low. The output of the XOR gate 102 is logic low when the synchronization flip flops 108, 110, and 112 are not propagating a change from one clock domain to the other domain, which is determined by comparing the asynchronous input signal (LEVEL_ASYNC) and the synchronous output signal (LEVEL_SYNC). There are usually two or three synchronization flip flops in the synchronizer flop bank; other embodiments of the synchronizer may include a number of flip flops other than two or three in the synchronizer flop bank.

The clock gating logic in the level synchronizer 10 of FIG. 1 only propagates the clock signal (CLK) when the asynchronous level-based signal input (LEVEL_ASYNC) is different from the synchronous level-based signal output (LEVEL_SYNC) and the reset is inactive (RSTN =1), otherwise the clock gating logic gates the clock signal (CLK) to save power. In another embodiment, an active high reset signal is used instead of the active low reset signal, a clock gating logic in the level synchronizer 10 only propagates the clock signal (CLK) when the asynchronous level-based signal input (LEVEL_ASYNC) is different from the synchronous level-based signal output (LEVEL_SYNC) and the reset is inactive (RST =0), otherwise the clock gating logic gates the clock signal (CLK).

FIG. 1 illustrates the clock gating logic implemented in a level synchronizer 10, in some other embodiments, the same concept of clock gating can be applied to other synchronizer designs such as a reset synchronizer, a level synchronizer with no reset, and a level synchronizer with synchronous reset input. FIG. 2 illustrates an internal structure of a reset synchronizer 20 used for synchronizing active high asynchronous resets according to an embodiment. The asynchronous reset input (RST_ASYNC) is the input of this reset synchronizer 20 and the synchronous reset output (RST_SYNC) is the output of the reset synchronizer 20. The reset input and output are active high, for example, RST_ASYNC=1 indicates reset while RST_ASYNC=0 indicates not reset. In this embodiment, the clock gating logic includes an AND gate 202, and a CG latch 204. The AND gate 202 connects to the synchronous reset output and inverted asynchronous reset input. An output of the AND gate 202 is connected to the CG latch 204 which adaptively propagates or gates the clock signal (CLK) to the flip flops 206, 208, and 210. The clock gating logic 204 enables clock propagation when the synchronous reset output is active (i.e. logic 1) and the asynchronous reset input is not active (i.e. logic 0), otherwise the clock gating logic 204 gates the clock signal (CLK) to synchronization flip flops 206, 208, and 210 in the reset synchronizer 20 to preserve the power consumption. In this embodiment, the clock signal (CLK) is a sampling clock having active rising edges, and the reset synchronizer 20 is a 3-stage synchroniser as there are three synchronization flip flops 206, 208, and 210. In this embodiment, the first synchronization flip flop 206 receives a logic 0 from its input D, the output Q of the first synchronization flip flop 206 is connected to the input D of the second synchronization flip flop 208, and the output of the second synchronization flip flop 208 is connected to the input D of the third synchronization flip flop 210. The output of the third synchronization flip flop 210 is the synchronous reset output.

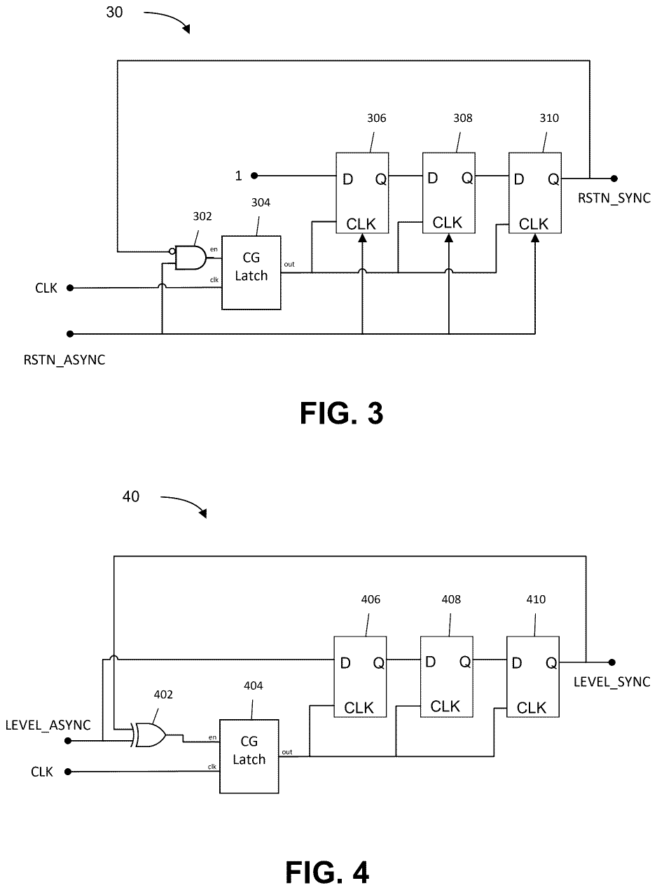

FIG. 3 illustrates an internal structure of another embodiment of the reset synchronizer 30 used for synchronizing active low asynchronous resets. Similar to the embodiment shown in FIG. 2, there are three synchronization flip flops 306, 308, and 310 in the synchronizer flop bank. The difference between these two embodiments is the input of the first synchronization flip flop 306 is a logic 1 instead of a logic 0. The input of this reset synchronizer 30 is an active low asynchronous reset input (RSTN_ASYNC), that is, RSTN_ASYNC=0 indicates reset while RSTN_ASYNC=1 indicates not reset. The clock gating logic determines whether to gate the clock signal (CLK) by inputting the active low asynchronous reset input and an inverted active low synchronous reset output (RST_SYNC) to an AND gate 302, and the output of the AND gate 302 is fed to the CG latch 304. The CG latch 304 gates the clock signal (CLK) when either the synchronous reset output is logic high (RSTN_SYNC=1) or when the active low asynchronous reset input indicates reset (RSTN_ASYNC=0). The synchronous reset output stays logic high when the synchronization flip flops 306, 308, and 310 are not toggling.

FIG. 4 illustrates an internal structure of a level synchronizer 40 according to an embodiment of the present invention. This embodiment is similar to the level synchronizer 10 as shown in FIG. 1 except there is no reset signal input to the level synchronizer 40. The clock gating logic includes an XOR gate 402 receiving an asynchronous input signal (LEVEL_ASYNC) and a synchronous output signal (LEVEL_SYNC), and a CG latch 404 receiving an output of the XOR gate 402 from its enable pin and a clock signal (CLK) from its clock pin. The CG latch 404 gates the synchronous flip flops 406, 408, and 410 when the asynchronous input signal and the synchronous output signal are both logic low or both logic high, indicating there is no level difference between the asynchronous input signal and the synchronous output signal.

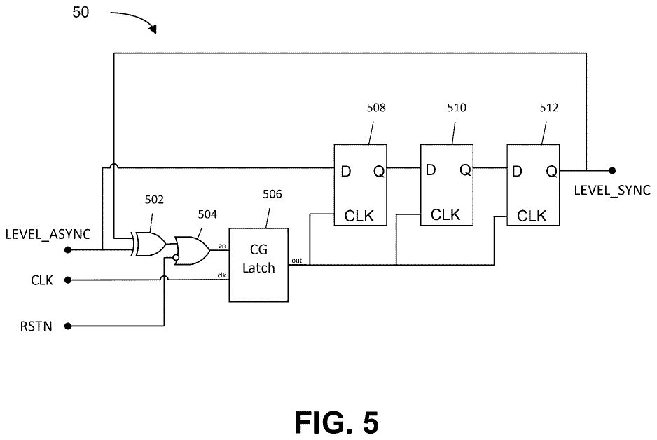

FIG. 5 illustrates an internal structure of a level synchronizer 50 with a synchronous reset input (RSTN) according to an embodiment of the present invention. The reset signal in FIG. 1 is an asynchronous reset signal, whereas the reset signal in FIG. 5 is a synchronous reset signal. A clock gating logic in this level synchronizer 50 includes an XOR gate 502, an OR gate 504, and a CG latch 506. The XOR gate 502 receives an asynchronous input signal (LEVEL_ASYNC) and a synchronous output signal (LEVEL_SYNC). The output of the XOR gate 502 is logic high if one of the two input signals LEVEL_ASYNC and LEVEL_SYNC is logic high while the other is logic low. The output of this XOR gate 502 and an inverted active low synchronous reset signal (RSTN_SYNC) are fed to the OR gate 504, and the output of the OR gate 504 is coupled to the enable pin of the CG latch 506 to control whether to gate or propagate the clock signal (CLK) into the synchronization flip flops 508, 510, and 512.

Some conventional approaches determine whether to enable clock gating depending on inevitably metastable intermediate outputs from all the intermediate stages. Embodiments of the present invention enable synchronizer clock gating according to a comparison between the input and output of the synchronizer, which is less prone to unexpected behavior caused by metastability and glitches. The logic circuit of the synchronizer is smaller with less combinatorial logic. Embodiments of the synchronizer with a clock gating logic require the input signal to last at least a predetermined number of clock cycles to enable the clock gating logic to ungate the clock signal. The predetermined number of clock cycles depends on the number of stages, which is also the number of flip flops in the synchronizer flop bank. For example, the input signal needs to last at least 3 clock cycles to allow the clock gating logic to propagate the clock signal when the synchronizer is a 3-stage synchronizer having 3 flip flops.

In some embodiments of the clock gating logic, only asynchronous input and synchronous output signals are required to determine whether to gate or propagate the clock signal to the synchronizer between two clock domains or two reset domains. The clock gating logic gates the clock signal when the input and output signals are the same. In some other embodiments, a reset signal is also used to control the clock gating logic in addition to the asynchronous input and the synchronous output. In case of asynchronous reset input, the clock gating logic only propagates the clock signal when the input and output signals are different and the reset signal is inactive, otherwise the clock gating logic gates the clock signal. This approach further reduces the power consumption as some digital modules stay in reset permanently unless software enables them for use. In case of synchronous reset input, the clock gating logic only propagates the clock signal to the synchronization flop bank when the input and output signals are different or when the reset signal is active, otherwise the clock gating logic gates the clock signal. This approach makes sure that synchronously reset logic gets properly flushed during reset conditions.

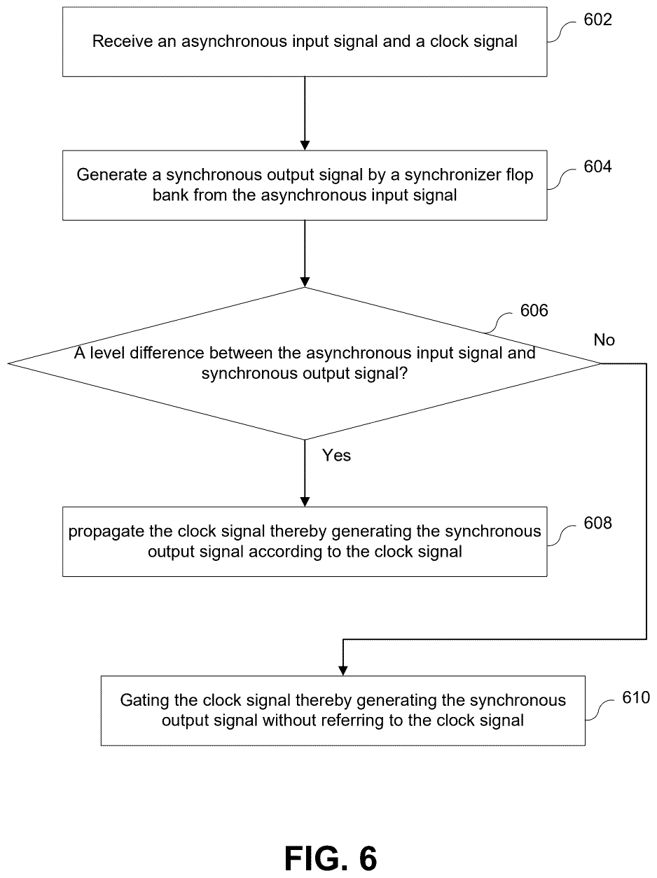

FIG. 6 is a flowchart illustrating an embodiment of a synchronizing method for synchronizing data transfer across a domain boundary between two digital systems. The two digital systems may be operated in different clock domains or in different reset domains. In step 602, an asynchronous input signal and a clock signal are received, and a synchronizer flop bank generates a synchronous output signal from the asynchronous input signal in step 604. In step 606, the method determines whether there is a level difference between the asynchronous input signal and synchronous output signal. The method includes propagating the clock signal thereby generating the synchronous output signal according to the clock signal in step 608 upon determining there is a level difference in step 606. The method includes gating the clock signal thereby generating the synchronous output signal without referring to the clock signal in step 610 if there is no level difference detected in step 606.

Although the invention is illustrated and described herein with reference to specific embodiments, the invention is not intended to be limited to the details shown. Rather, various modifications may be made in the details within the scope and range of equivalents of the claims and without departing from the invention. It is to be understood that the above description is illustrative of the invention and is not to be construed as limiting the invention. Various modifications, applications and/or combinations of the embodiments may occur to those skilled in the art without departing from the scope of the invention as defined by the claims. Well-known circuits, processes, algorithms, structures, and techniques may be shown without unnecessary detail to avoid obscuring the aspects.

Processes and methods according to the above-described examples can be implemented using computer-executable instructions that are stored or otherwise available from computer-readable media. Such instructions can include, for example, instructions and data which cause or otherwise configure a general-purpose computer, special purpose computer, or a processing device to perform a certain function or group of functions. Portions of computer resources used can be accessible over a network. The computer executable instructions may be, for example, binaries, intermediate format instructions such as assembly language, firmware, source code, etc. Devices implementing processes and methods according to these disclosures can include hardware, software, firmware, middleware, microcode, hardware description languages, or any combination thereof, and can take any of a variety of form factors. When implemented in software, firmware, middleware, or microcode, the program code or code segments to perform the necessary tasks may be stored in a computer-readable or machine-readable medium. The computer-readable medium may comprise memory or data storage media, such as Random-Access Memory (RAM) such as Synchronous Dynamic Random-Access Memory (SDRAM), Read-Only Memory (ROM), Non-Volatile Random-Access Memory (NVRAM), Electrically Erasable Programmable Read-Only Memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves. The program code may be executed by a processor, which may include one or more processors, such as one or more Digital Signal Processors (DSPs), general purpose microprocessors, an Application Specific Integrated Circuits (ASICs), Field Programmable Logic Arrays (FPGAs), or other equivalent integrated or discrete logic circuitry. Such a processor may be configured to perform any of the steps described in this disclosure. A general-purpose processor may be a microprocessor; alternatively, the processor may be any conventional processor, controller, microcontroller, or state machine. A processor may also be implemented as a combination of computing devices.

To clearly illustrate the interchangeability of hardware and software, various illustrative components, blocks, modules, engines, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present application.

What is claimed is:

1. A digital circuit having multiple digital systems, comprising:
a first digital system, operating in a first domain;
a second digital system, operating in a second domain; and
a synchronizer, coupled to the first and second digital systems for synchronizing data transfer operations across a domain boundary between the first and second domains, generating a synchronous output signal for the second digital system from an asynchronous input signal receiving from the first digital system, wherein the synchronizer comprises:
a clock gating logic, for receiving the asynchronous input signal, the synchronous output signal, and a clock signal, and adaptively gating the clock signal according to the asynchronous input signal and the synchronous output signal; and
a synchronizer flop bank comprising a number of synchronization flip flops, for receiving the asynchronous input signal and the clock signal to generate the synchronous output signal, wherein the clock signal is adaptively gated by the clock gating logic.

2. The digital circuit of claim 1, wherein the first domain and second domain are different clock domains operating at different clock frequencies.

3. The digital circuit of claim 1, wherein the first domain and second domain are different reset domains, resetting by different reset signals.

4. The digital circuit of claim 1, wherein the clock gating logic propagates the clock signal upon detecting there is a level difference between the asynchronous input signal and the synchronous output signal, wherein the clock gating logic gates the clock signal upon detecting no level difference exists between the asynchronous input signal and the synchronous output signal.

5. The digital circuit of claim 4, wherein the clock gating logic transitions from gating the clock signal to propagate the clock signal after detecting a level difference between the asynchronous input signal and synchronous output signal last for at least a predetermined number of clock cycles, wherein the predetermined number of clock cycles corresponds to the number of synchronization flip flops in the synchronizer flop bank.

6. The digital circuit of claim 4, wherein the clock gating logic comprises an XOR gate and a clock gate latch, inputs to the XOR gate are the asynchronous input signal and the synchronous output signal, an output of the XOR gate is coupled to an enable pin of the clock gate latch, and the clock signal is coupled to a clock pin of the clock gate latch; wherein the clock gating logic gates the clock signal for the synchronizer flop bank when there is no level difference between the asynchronous input signal and the synchronous output signal.

7. The digital circuit of claim 1, wherein the synchronizer further receives an asynchronous reset signal, and the clock gating logic only propagates the clock signal upon detecting a level difference between the asynchronous input signal and synchronous output signal and the asynchronous reset signal is inactive.

8. The digital circuit of claim 7, wherein the clock gating logic comprises an XOR gate, an AND gate, and a clock gate latch, inputs to the XOR gate are the asynchronous input signal and the synchronous output signal, inputs to the AND gate are the asynchronous reset signal and an output of the XOR gate, and an output of the AND gate is coupled to an enable pin of the clock gate latch, and the clock signal is coupled to a clock pin of the clock gate latch, wherein the clock gate latch adaptively gates the clock signal for the synchronizer flop bank according to the output of the AND gate.

9. The digital circuit of claim 1, wherein the synchronizer further receives a synchronous reset signal, and the clock gating logic only propagates the clock signal upon detecting a level difference between the asynchronous input signal and the synchronous output signal or the synchronous reset signal is active.

10. The digital circuit of claim 9, wherein the clock gating logic comprises an XOR gate, an OR gate, and a clock gate latch, inputs to the XOR gate are the asynchronous input signal and the synchronous output signal, inputs to the OR gate are the synchronous reset signal and an output of the XOR gate, and an output of the OR gate is coupled to an enable pin of the clock gate latch and the clock signal is coupled to a clock pin of the clock gate latch, wherein the clock gate latch adaptively gates the clock signal for the synchronizer flop bank according to the output of the OR gate.

11. The digital circuit of claim 1, wherein the synchronizer comprises a reset synchronizer used for synchronizing logic high or logic low asynchronous resets, a level synchronizer for level-based data or control signal synchronization, and a pulse synchronizer for pulse-based data or control signal synchronization.

12. The digital circuit of claim 11, wherein the level synchronizer receives a synchronous reset input or an asynchronous reset input.

13. A synchronizing method for synchronizing data transfer across a domain boundary between a first digital system and a second digital system, the synchronizing method comprising:
receiving an asynchronous input signal from the first digital system;
receiving a clock signal for synchronizing the asynchronous input signal;
generating a synchronous output signal by a synchronizer flop bank from the asynchronous input signal;
detecting if there is a level difference between the asynchronous input signal and synchronous output signal; and
controlling a delivery of the clock signal to the synchronizer flop bank through a clock gating logic based on the detecting result, wherein the clock signal is gated upon detecting there is no level difference between the asynchronous input signal and synchronous output signal.

14. The synchronizing method of claim 13, further comprising receiving an asynchronous reset signal, wherein the clock gating logic propagates the clock signal when a level difference is detected between the asynchronous input signal and the synchronous output signal and when the asynchronous reset signal is inactive, otherwise the clock gating logic gates the clock signal.

15. The synchronizing method of claim 13, further comprising receiving a synchronous reset signal, wherein the clock gating logic propagates the clock signal when a level difference is detected between the asynchronous input signal and the synchronous output signal or when the synchronous reset signal is active, otherwise the clock gating logic gates the clock signal.

16. The synchronizing method of claim 13, wherein the clock gating logic transitions from gating the clock signal to propagate the clock signal after detecting a level difference between the synchronous input signal and synchronous output signal last for at least a predetermined number of clock cycles.
